(19) United States
(12) Patent Application Publication
(10) Pub. No.: US 2023/0163583 A1
(43) Pub. Date: May 25, 2023

(54) ELECTRICAL JUNCTION BOX

(71) Applicant: Sumitomo Wiring Systems, Ltd., Yokkaichi-shi, Mie (JP)

(72) Inventors: Yuya MATSUO, Yokkaichi-shi, Mie (JP); Akihiro ODA, Yokkaichi-shi, Mie (JP); Tatsuya DAIDOJI, Yokkaichi-shi, Mie (JP); Noriko OKAMOTO, Yokkaichi-shi, Mie (JP); Ryoma HOMADA, Yokkaichi-shi, Mie (JP)

(21) Appl. No.: 17/904,231

(22) PCT Filed: Feb. 5, 2021
(86) PCT No.: PCT/JP2021/004312

§ 371 Date: Feb. 15, 2023

(30) Foreign Application Priority Data
Feb. 21, 2020 (JP) 2020-028502

(51) Int. Cl. H02G 3/16; H02G 3/08; H01R 13/688

(52) U.S. Cl. CPC H02G 3/16; H02G 3/081; H01R 13/688

(57) ABSTRACT

Provided is an electrical junction box (100) including a housing (30) that houses a substrate (21) to which a fixed fuse (10) is soldered. The housing (30) includes a checking opening (33) for checking whether or not the fixed fuse (10) has been blown out.

### TECHNICAL FIELD

The present disclosure relates to an electrical junction box.

The present application claims the benefit of priority based on Japanese Patent Application No. 2020-028502 filed Feb. 21, 2020, the entire content of which is hereby incorporated by reference.

### BACKGROUND ART

Conventionally, vehicular electrical junction boxes for electrically connecting a battery and various electrical components have become widely spread. Many vehicles are provided with an electrical junction box that is disposed between a power supply and electrical components to supply power to them. In an electrical junction box, a housing houses components such as a substrate, busbars, and fuses.

Patent Document 1 discloses an electrical junction box that includes a busbar and a current sensor for detecting an electric current flowing through the busbar, and in which a chamber for housing the current sensor has a checking window through which a part of the current sensor is exposed, so that it is possible to check, through the checking window, whether or not the current sensor is housed.

### CITATION LIST

### Patent Document

Patent Document 1: JP 2009-100574A

### SUMMARY OF INVENTION

An electrical junction box according to an embodiment of the present disclosure relates to an electrical junction box including a housing that houses a substrate on which a fuse is mounted, wherein the housing has a checking window for checking whether or not the fuse has been blown out.

### BRIEF DESCRIPTION OF DRAWINGS

FIG. 1 is a perspective view illustrating an outer appearance of an electrical junction box according to Embodiment 1.

FIG. 2 is a perspective view illustrating a state of the electrical junction box according to Embodiment 1 where an upper case part is removed.

FIG. 3 is a perspective view illustrating a substrate assembly according to Embodiment 1.

FIG. 4 is a plan view of the electrical junction box according to Embodiment 1.

FIG. 5 is a perspective view illustrating an outer appearance of an electrical junction box according to Embodiment 2.

FIG. 6 is a perspective view illustrating an outer appearance of an electrical junction box according to Embodiment 3.

FIG. 7 is a perspective view illustrating an outer appearance of an electrical junction box according to Embodiment 4.

### DESCRIPTION OF EMBODIMENTS

### Problems to be Solved by Present Disclosure

As fuses for protecting a circuit when an overcurrent flows, there are replaceable fuses and fixed fuses, which are used depending on the application. Replaceable fuses and fixed fuses are mounted on a corresponding substrate by different methods.

Replaceable fuses are fuses that are from the beginning expected to be replaced at some time, and are detachably connected to a substrate via holding members for temporarily holding the fuses. Also, fixed fuses are fuses that are originally not expected to be replaced, and are directly fixed to a substrate by, for example, soldering.

Also, in many electrical junction box, a housing that houses a substrate has a replacement opening for use in replacing replaceable fuses, and the replaceable fuses are exposed via the replacement opening. Accordingly, if an electrical trouble occurs, a user can easily check, through the replacement opening, whether or not any of the replaceable fuses has been blown out, and can replace the replaceable fuse without disassembling the housing.

On the other hand, if, in the event of an electrical trouble, it is found that no replaceable fuse has been blown out, it is also necessary to check whether or not any of the fixed fuses has been blown out. This results in a problem that it is not possible to check the fixed fuses without disassembling the housing.

However, the electrical junction box of Patent Document 1 does not mention any method for checking fixed fuses, and thus cannot solve this problem.

The present invention was made in view of the above-described circumstances, and it is an object thereof to provide an electrical junction box for which a user can check whether or not a fixed fuse housed in a housing has been blown out, more easily.

### Advantageous Effects of Present Disclosure

According to the present disclosure, it is possible to check whether or not any fixed fuse housed in a housing has been blown out, more easily.

### Description of Embodiments of Present Invention

First, embodiments of the present disclosure will be listed and described. Also, at least some of the embodiments described below may be combined with each other as appropriate.

(1) According to an embodiment of the present disclosure, an electrical junction box includes a housing that houses a substrate to which a fuse is soldered, wherein the housing includes a checking opening for checking whether or not the fuse has been blown out.

In this embodiment, since the housing includes the checking opening for checking whether or not the fuse soldered to the substrate has been blown out, it is possible to easily check whether or not any fuse has been blown out, without disassembling this housing.

(2) The electrical junction box according to an embodiment of the present disclosure further includes a lid member for covering the checking opening.

In this embodiment, since the lid member covers the checking opening, it is possible to prevent dust or the like from entering the housing via the checking opening.

(3) In the electrical junction box according to an embodiment of the present disclosure, the lid member can open and close.

In this embodiment, since the lid member can open and close, a user can open the lid member and performs a predetermined treatment on the fuse via the checking opening, for example.

(4) In the electrical junction box according to an embodiment of the present disclosure, the lid member includes a transparent part.

In this embodiment, since the lid member includes a transparent part, the user can check whether or not any fuse has been blown out from this transparent part, without opening the lid member.

(5) In the electrical junction box according to an embodiment of the present disclosure, the housing has a flat cuboid shape, the substrate is arranged facing two main surfaces of the housing, and the checking opening is formed in one of the main surfaces at a position that corresponds to the fuse.

In this embodiment, since the checking opening is formed in the main surface on the mounting surface side of the substrate at a position that corresponds to the fuse when viewed in the thickness direction of the substrate, it is possible to easily check whether or not the fuse has been blown out, and perform a corresponding treatment, for example.

(6) In the electrical junction box according to an embodiment of the present disclosure, the housing has a flat cuboid shape, the substrate is arranged facing two main surfaces of the housing, and the checking opening is formed in a side surface of the housing that is closest to the fuse.

In this embodiment, since the checking opening is formed in a side surface of the housing that is closest to the fuse, it is possible to easily check whether or not the fuse has been blown out, and perform the corresponding treatment, for example.

(7) In the electrical junction box according to an embodiment of the present disclosure, the housing has a flat cuboid shape, the substrate is arranged facing two main surfaces of the housing, and the checking opening is formed in a side surface of the housing that is closest to the fuse, while extending over the two main surfaces.

In this embodiment, since the checking opening is formed in a side surface of the housing that is closest to the fuse, while extending over the two main surfaces, it is possible to easily check whether or not the fuse has been blown out. Also, for example, when, in the event of a blowout of the fuse, a user inserts a soldering iron or the like into the checking opening and performs a treatment, it is possible to increase the convenience of the operation.

### DETAILS OF EMBODIMENTS OF PRESENT INVENTION

The following will describe the electrical junction box according to embodiments of the present disclosure with reference to the drawings. Note that the present invention is not limited to the examples but is defined by the claims, and all modifications within the meaning and scope equivalent to the claims are intended to be included.

### Embodiment 1

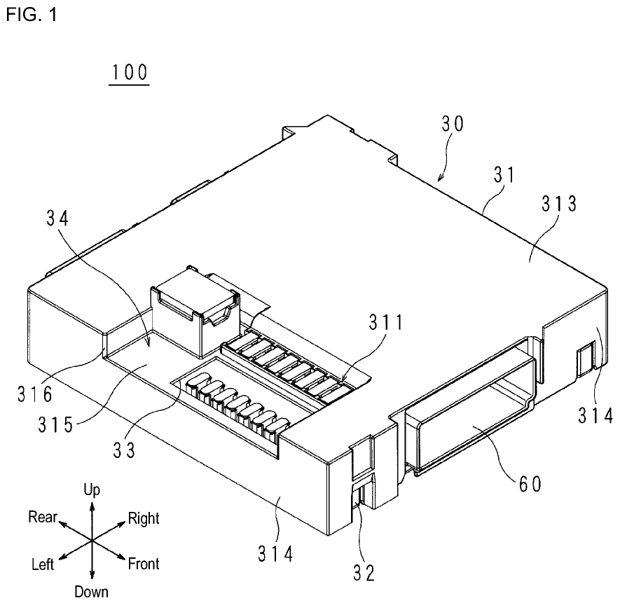

FIG. 1 is a perspective view illustrating an outer appearance of an electrical junction box 100 according to Embodiment 1. The electrical junction box 100 is a so-called vehicular junction box provided with fuses.

In the present embodiments, for convenience, “front”, “rear”, “left”, “right”, “up”, and “down” of the electrical junction box 100 are defined based on the front-rear direction, left-right direction, and up-down direction of the drawings. The following description will be given based on the front-rear direction, the left-right direction, and the up-down direction thus defined.

The electrical junction box 100 includes a case member 30 that houses a later-described substrate assembly 20. The case member 30 has a flat cuboid shape, and includes an upper case part 31 and a lower case part 32. The upper case part 31 is a housing whose lower face is open, and the lower case part 32 is a housing whose upper face is open. The upper case part 31 covers the lower case part 32 and forms one piece therewith, and the substrate assembly 20 is attached to the lower case part 32.

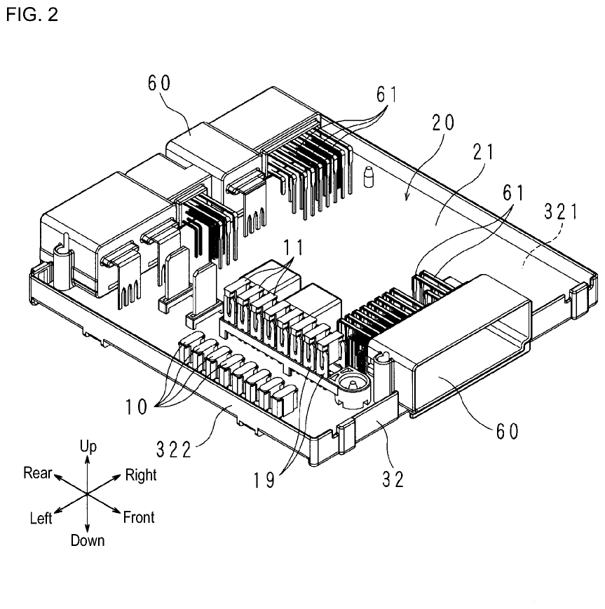

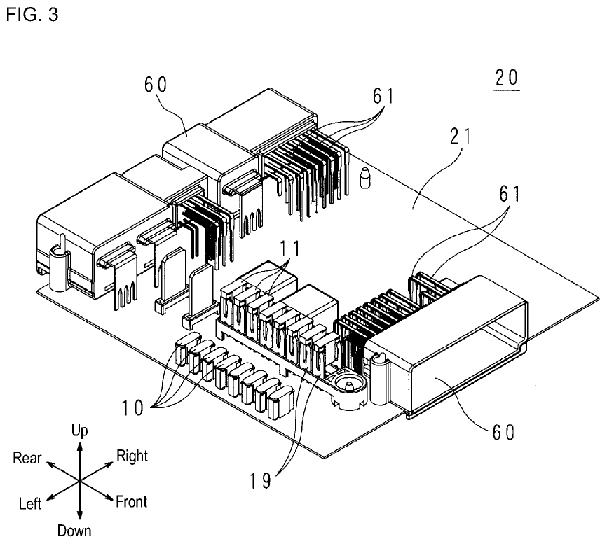

FIG. 2 is a perspective view illustrating a state of the electrical junction box 100 according to Embodiment 1 where the upper case part 31 is removed. FIG. 3 is a perspective view illustrating the substrate assembly 20 according to Embodiment 1.

The upper case part 31 includes a substantially rectangular ceiling plate 313 (main surface), and side plates 314 extending perpendicularly downward from side edges of the ceiling plate 313. The upper case part 31 has a recess 34 in the region of the left-side edge thereof.

The lower case part 32 has a rectangular bottom plate 321 (main surface), and side plates 322 standing upright from side edges of the bottom plate 321. The substrate assembly 20 is attached to the bottom plate 321. The bottom plate 321 faces the ceiling plate 313.

The substrate assembly 20 includes a substrate 21 that covers substantially the entire surface of the bottom plate 321 of the lower case part 32, and circuit components mounted on the upper surface of the substrate 21. That is to say, the substrate 21 faces the bottom plate 321 and the ceiling plate 313.

Furthermore, the substrate 21 is provided with one connection port 60 in a front-side edge portion, and two connection ports 60 in a rear-side edge portion. The connection ports 60 are connected to the substrate 21 via connection terminals 61 that are bent in an L shape. Cutouts are formed in the side plates 314 of the upper case part 31 on the front and rear sides and in the side plates 322 of the lower case part 32 on the front and rear sides, and the connection ports 60 protrude to the outside of the case member 30 via the cutouts of the side plates 314 and the cutouts of the side plates 322.

Also, two types of fuses, namely, a plurality of replaceable fuses 11 and a plurality of fixed fuses 10, are mounted on the substrate 21. The plurality of fixed fuses 10 are lined up in a row along the left-side edge of the substrate 21, and the plurality of replaceable fuses 11 are lined up in a row on the side closer to a central portion of the substrate 21 than the fixed fuses 10 are. The fixed fuses 10 are mounted at an interval therebetween that is greater than the interval at which the replaceable fuses 11 are mounted.

The replaceable fuses 11 are from the beginning expected to be replaced at some time, and are held on the substrate 21 so as to be detachable. The fixed fuses 10 are not expected to be replaced, and are fixed to the substrate 21.

The replaceable fuses 11 are connected, via holding terminals 19, to a printed wiring board (not shown) or the like formed on the substrate 21. Aplurality of holding terminals 19 are lined up in the front-rear direction. Each holding terminal 19 has a pair of U-shaped pinching parts, and the pair of pinching parts are disposed in parallel to each other in the left-right direction.

Each replaceable fuse 11 is attached spanning the space between the pair of pinching parts of the corresponding holding terminal 19, and is detachably held. That is to say, the replaceable fuse 11 can be replaced by being inserted into and retracted from the holding terminal 19. Therefore, the replaceable fuses 11 are easily replaceable.

In contrast, the fixed fuses 10 are fixed to the printed wiring of the substrate 21 by soldering. Therefore, the fixed fuses 10 are not easily replaceable.

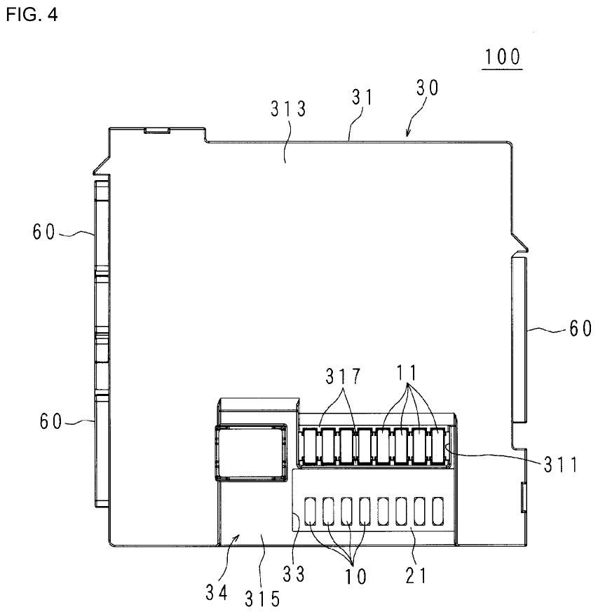

FIG. 4 is a plan view of the electrical junction box 100 according to Embodiment 1.

The recess 34 has a step part 315 formed on the ceiling plate 313 of the upper case part 31, and a cutout 316 formed in the side plate 314. A replacement window 311 is formed in the step part 315. The replacement window 311 penetrates the ceiling plate 313 in the thickness direction, and is formed at a position matching the positions of the plurality of replaceable fuses 11 when viewed in the thickness direction (up-down direction) of the case member 30.

As described above, since the plurality of replaceable fuses 11 are lined up in a row, the replacement window 311 has the shape of a rectangle whose longitudinal direction conforms to the direction in which the plurality of replaceable fuses 11 are lined up. Also, a pair of guide frames 317, which are comb-shaped, are provided on the step part 315 along the long sides of the replacement window 311. The pair of guide frames 317 are provided in a manner such that the open side of the guide frames 317 face each other. Each of the guide frames 317 has inside-oriented grooves at equal intervals, the number of grooves corresponding to the number of the plurality of replaceable fuses 11.

All of the replaceable fuses 11 are exposed to the outside of the case member 30 via the replacement window 311. Accordingly, when a replaceable fuse 11 is blown out, a user can replace this replaceable fuse 11 through the replacement window 311. At this time, the insertion and removal of the replaceable fuse 11 are guided by the guide frames 317.

Also, the step part 315 of the upper case part 31 includes a checking opening 33 for checking whether or not any fixed fuse 10 has been blown out. The checking opening 33 penetrates the ceiling plate 313 in the thickness direction, and is formed at a position matching the positions of the plurality of fixed fuses 10 when viewed in the thickness direction of the case member 30.

As described above, since the plurality of fixed fuses 10 are lined up in a row, the checking opening 33 has the shape of a rectangle whose longitudinal direction conforms to the direction in which the plurality of fixed fuses 10 are lined up. That is to say, the checking opening 33 is rectangular, corresponding to the region of the substrate 21 in which the plurality of fixed fuses 10 are lined up, and has a length and a width that are sufficiently larger than those of the region in which the plurality of fixed fuses 10 are lined up.

All of the fixed fuses 10 are exposed to the outside of the case member 30 via the checking opening 33. Accordingly, the user can check, through the checking opening 33, whether or not any fixed fuse 10 has been blown out.

Also, as described above, the distance between the fixed fuses 10 is larger than the distance between the replaceable fuses 11, and the short-side dimension (in the width direction) of the checking opening 33 is sufficiently larger than the long-side dimension of the fixed fuses 10. Accordingly, if it is found that a fixed fuse 10 has been blown out, the user can insert, through the checking opening 33, the distal end of a soldering iron to melt the solder, and remove and replace the blown-out fixed fuse 10. Therefore, it is possible to save time and effort to disassemble the case member 30 for replacement of the fixed fuse 10 and the like, and perform such replacement promptly.

In the electrical junction box 100 according to Embodiment 1, the short-side dimension (width) of the checking opening 33 is not limited to the description above. It is sufficient that the short-side dimension of the checking opening 33 is sufficiently larger than the dimension (hereinafter, long-side dimension) of the fixed fuses 10 in a direction orthogonal to the direction in which the plurality of fixed fuses 10 are lined up, to the extent that it is possible to insert the distal end of a soldering iron via the checking opening 33 to melt the solder and remove the fixed fuse 10. For example, the short-side dimension of the checking opening 33 is preferably at least 1.5 times as large as the long-side dimension of the fixed fuses 10.

Note that, for example, the checking opening 33 may also be configured to have a transparent or translucent window. In this case, it is possible to prevent dust or the like from entering the case member 30 via the checking opening 33.

### Embodiment 2

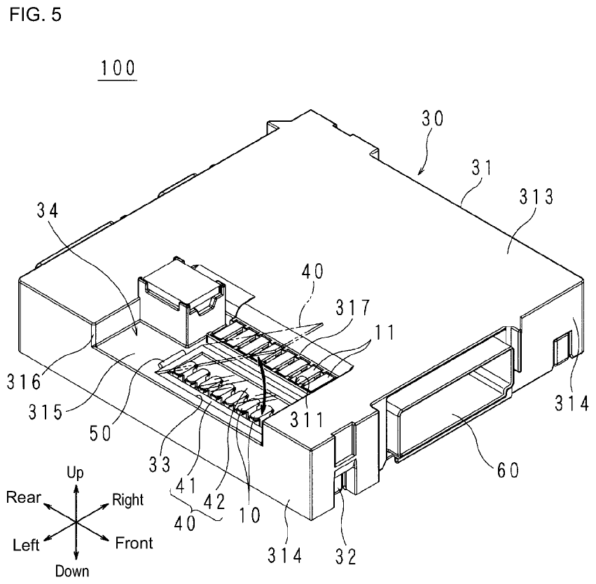

FIG. 5 is a perspective view illustrating an outer appearance of an electrical junction box 100 according to Embodiment 2.

Similar to Embodiment 1, the electrical junction box 100 according to Embodiment 2 includes a case member 30, and the case member 30 includes a substrate 21, a plurality of replaceable fuses 11 held on the substrate 21 so as to be detachable, and a plurality of fixed fuses 10 fixed to the substrate 21.

Also, the step part 315 of the upper case part 31 includes a replacement window 311 for replacing the replaceable fuses 11, the replacement window 311 being formed at a position matching the positions of the plurality of replaceable fuses 11 when viewed in the thickness direction (up-down direction) of the case member 30.

Furthermore, the step part 315 of the upper case part 31 includes a checking opening 33 for checking whether or not any fixed fuse 10 has been blown out. The checking opening 33 penetrates the ceiling plate 313 in the thickness direction, and is formed at a position matching the positions of the plurality of fixed fuses 10 when viewed in the thickness direction of the case member 30.

The checking opening 33 is rectangular corresponding to the region of the substrate 21 in which the plurality of fixed fuses 10 are lined up, and is formed along the direction in which the plurality of fixed fuses 10 are lined up. The checking opening 33 has a length and a width that are sufficiently larger than those of the region in which the plurality of fixed fuses 10 are lined up.

The electrical junction box 100 according to Embodiment 2 further includes a lid member 40 that covers the checking opening 33 and can open and close. The lid member 40 is rectangular corresponding to the checking opening 33, and has a dimension slightly larger than that of the checking opening 33, for example.

The lid member 40 includes a window part (transparent part) 42 and a frame part 41. The window part 42 is located in the center of the lid member 40, is made of a resin, a glass, or the like, and is transparent or translucent. The frame part 41 is a rectangular frame and is made of a resin. The window part 42 is surrounded by the frame part 41.

On the step part 315 of the upper case part 31, a hinge 50 for rotating the lid member 40 is provided in the region of the shot-side of the checking opening 33.

One of the short sides of the lid member 40 is coupled to the hinge 50, and the lid member 40 rotates about the axis of the hinge 50 (see the dashed-two dotted line in FIG. 5). By rotating in this way, the lid member 40 opens and closes the checking opening 33 (see the arrow in FIG. 5).

In the electrical junction box 100 according to Embodiment 2 having the above-described configuration, the user can immediately check, through the window part 42 of the lid member 40, whether or not any fixed fuse 10 has been blown out.

Also, since the checking opening 33 is covered by the lid member 40, it is possible to prevent dust or the like from entering the case member 30 via the checking opening 33.

Furthermore, since the lid member 40 can open and close, when it is found that any fixed fuse 10 has been blown out, the user can open the lid member 40, insert the distal end of a soldering iron into the case member 30 from the checking opening 33 to melt the solder, and remove and replace the blown-out fixed fuse 10. Therefore, it is possible to save time and effort to disassemble the case member 30 for replacement of the fixed fuse 10 and the like, and perform such replacement promptly

A case where the hinge 50 is provided in the region of a short-side of the checking opening 33 has been described as an example, but the present invention is not limited to this case. The hinge 50 may also be provided in the region of a long-side of the checking opening 33.

A configuration is also possible in which the lid member 40 has the same dimension as that of the checking opening 33, and the lid member 40 is fitted into the checking opening 33.

Note that the electrical junction box 100 according to Embodiment 2 is not limited to the description above. For example, a configuration is also possible in which the lid member 40 does not have any frame part 41, but is constituted only by the window part 42.

The same reference numerals are given to the same components as those of Embodiment 1, and detailed descriptions thereof are omitted.

### Embodiment 3

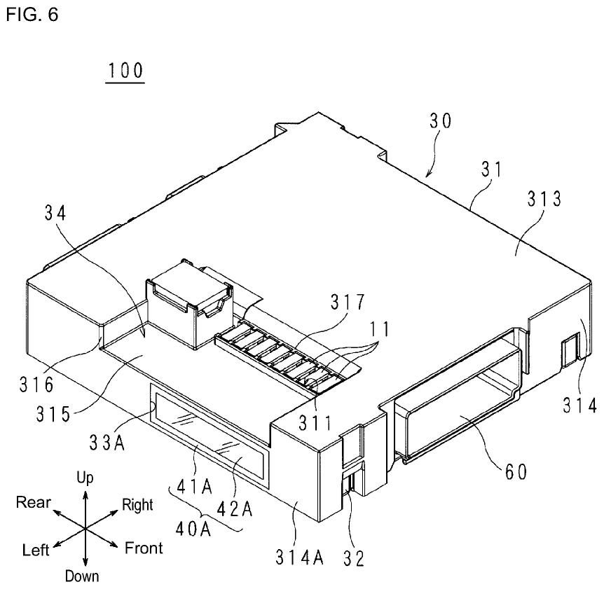

FIG. 6 is a perspective view illustrating an outer appearance of an electrical junction box 100 according to Embodiment 3.

Similar to Embodiment 1, the electrical junction box 100 according to Embodiment 3 includes a case member 30, and the case member 30 includes a substrate 21, a plurality of replaceable fuses 11 held on the substrate 21 so as to be detachable, and a plurality of fixed fuses 10 fixed to the substrate 21.

Also, the step part 315 of the upper case part 31 includes the replacement window 311 for replacing the replaceable fuses 11, the replacement window 311 being formed at a position matching the positions of the plurality of replaceable fuses 11 when viewed in the thickness direction (up-down direction) of the case member 30.

Furthermore, in the electrical junction box 100 according to Embodiment 3, a checking opening 33A for checking whether or not any fixed fuse 10 has been blown out is arranged in the side surface of the case member 30 that is closest to the plurality of fixed fuses 10.

That is to say, in the electrical junction box 100 according to Embodiment 3, similar to Embodiment 1, the plurality of fixed fuses 10 are mounted while being lined up in a row along the left-side edge of the substrate 21 (see FIG. 2), and the side surface of the case member 30 that is closest to the plurality of fixed fuses 10 is a side plate 314A of the cutout 316. Accordingly, in the electrical junction box 100 according to Embodiment 3, the checking opening 33A is formed in the side plate 314A.

The checking opening 33A penetrates the side plate 314A in the thickness direction. The checking opening 33A is rectangular corresponding to the region of the substrate 21 in which the plurality of fixed fuses 10 are lined up, and has a length that is sufficiently larger than that of the region in which the plurality of fixed fuses 10 are lined up. The long-side dimension (length) of the checking opening 33A is sufficiently larger than that of the region in which the plurality of fixed fuses 10 are lined up. Also, the short-side dimension (width) of the checking opening 33A is slightly smaller than the distance between the ceiling plate 313 (step part 315) and the bottom plate 321.

Also, the electrical junction box 100 according to Embodiment 3 includes a lid member 40A that covers the checking opening 33A. The lid member 40A is rectangular corresponding to the checking opening 33A, and has dimensions equal to those the checking opening 33A, for example.

The lid member 40A includes a window part 42A and a frame part 41A. The window part 42A is located in the center of the lid member 40A, is made of a resin, a glass, or the like, and is transparent or translucent. The frame part 41A is a rectangular frame and is made of a resin. The window part 42A is surrounded by the frame part 41A.

In the electrical junction box 100 according to Embodiment 3 having the above-described configuration, the user can immediately check, through the window part 42A of the lid member 40A, whether or not any fixed fuse 10 has been blown out.

Also, since the checking opening 33A is covered by the lid member 40A, it is possible to prevent dust or the like from entering the case member 30 via the checking opening 33A.

Ordinarily, each fuse has its own information indicated on a surface (upper surface) thereof that can be seen from the mounting surface side of the substrate. Accordingly, when the user checks whether or not any fuse has been blown out from the mounting surface side of the substrate, such indication of information may get in the way of the user's checking.

To solve the problem, in the electrical junction box 100 according to Embodiment 3, the checking opening 33A is formed in the side plate 314A of the case member 30 that is closest to the plurality of fixed fuses 10. Therefore, the user can check whether or not any fuse 10 has been blown out, in a direction orthogonal to the thickness direction of the substrate 21, that is, from the side surface of the fixed fuses 10. Accordingly, even when the fixed fuses 10 have their own information indicated thereon, it is possible to reliably check whether or not any fixed fuse 10 has been blown out.

A case where the checking opening 33A is formed in a portion of the side plate 314A has been described as an example, but the electrical junction box 100 according to Embodiment 3 is not limited to this. For example, the checking opening 33A may also be formed over the entire side plate 314A.

Also, the electrical junction box 100 according to Embodiment 3 is not limited to the description above. For example, a configuration is also possible in which the lid member 40A can open and close the checking opening 33A.

The same reference numerals are given to the same components as those of Embodiment 1, and detailed descriptions thereof are omitted.

### Embodiment 4

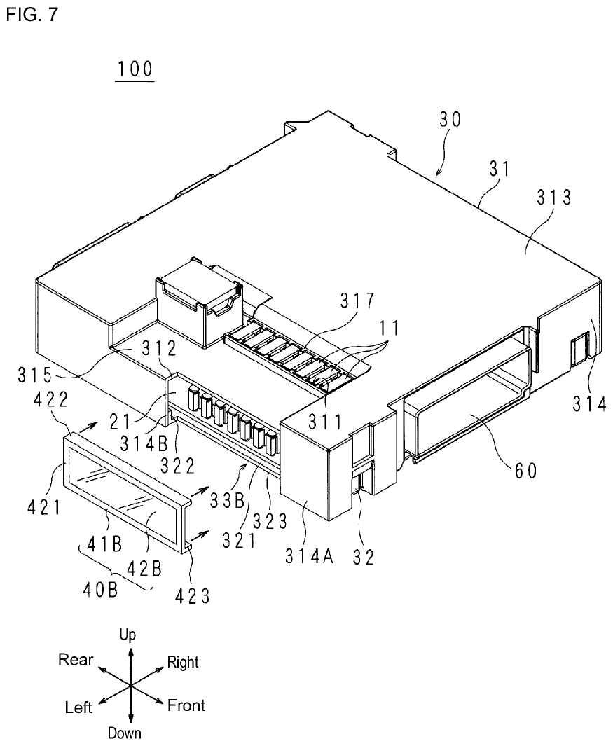

FIG. 7 is a perspective view illustrating an outer appearance of an electrical junction box 100 according to Embodiment 4. FIG. 7 shows a state before a later-described lid member 40B and a later-described checking opening 33B are engaged with each other.

Similar to Embodiment 1, the electrical junction box 100 according to Embodiment 4 includes a case member 30, and the case member 30 includes a substrate 21, a plurality of replaceable fuses 11 held on the substrate 21 so as to be detachable, and a plurality of fixed fuses 10 fixed to the substrate 21.

Also, the step part 315 of the upper case part 31 includes a replacement window 311 for replacing the replaceable fuses 11, the replacement window 311 being formed at a position matching the positions of the plurality of replaceable fuses 11 when viewed in the thickness direction (up-down direction) of the case member 30.

Furthermore, in the electrical junction box 100 according to Embodiment 4, the checking opening 33B for checking whether or not any fixed fuse 10 has been blown out is formed on the left side of the case member 30 that is close to the fixed fuses 10.

That is to say, in the electrical junction box 100 according to Embodiment 4, similar to Embodiment 1, the plurality of fixed fuses 10 are mounted while being lined up in a row along the left-side edge of the substrate 21 (see FIG. 2). Accordingly, in the electrical junction box 100 of Embodiment 4, the checking opening 33B is formed in the left side plate 314A of the case member 30. The checking opening 33 is open in the side plate 314A extending from the ceiling plate 313 to the bottom plate 321. The following will describe the details thereof.

The checking opening 33B is constituted by a rectangular opening portion 314B formed in a portion of the side plate 314A, a strip-shaped upper opening portion 312 that corresponds to the rectangular opening portion 314B and is formed at the edge of the ceiling plate 313 (step part 315) on the side plate 314A side, and a strip-shaped lower opening portion 323 that corresponds to the rectangular opening portion 314B and is formed at an edge of the bottom plate 321 on the side plate 314A side. The rectangular opening portion 314B, the strip-shaped upper opening portion 312, and the strip-shaped lower opening portion 323 are formed continuously.

The rectangular opening portion 314B penetrates side plate 314A in the thickness direction. The rectangular opening portion 314B has the shape of a rectangle whose longitudinal direction conforms to the direction (front-rear direction) in which the plurality of fixed fuses 10 are lined up. The long-side dimension of the rectangular opening portion 314B is sufficiently larger than the dimension, in the front-rear direction, of the region in which the plurality of fixed fuses 10 are lined up. Also, the short-side dimension of the rectangular opening portion 314B is substantially equal to the distance from the ceiling plate 313 (step part 315) to the bottom plate 321.

Also, the strip-shaped upper opening portion 312 is formed by cutting out the edge of the step part 315 on the side plate 314A side in a strip shape, and has a longitudinal dimension equal to the longitudinal dimension of the rectangular opening portion 314B in the longitudinal direction. Furthermore, the strip-shaped lower opening portion 323 is formed by cutting out the edge of the bottom plate 321 on the side plate 314A side in a strip shape, and has a longitudinal dimension equal to the longitudinal dimension of the rectangular opening portion 314B.

Furthermore, the electrical junction box 100 according to Embodiment 4 includes a lid member 40B that covers the checking opening 33B. The lid member 40B has a shape corresponding to the checking opening 33B. The lid member 40B has a substantially C-shaped cross-section, and closes the checking opening 33B by engaging with the checking opening 33B (see arrows in FIG. 7). That is to say, the lid member 40B opens and closes the checking opening 33B.

The lid member 40B includes a window part 42B and a frame part 41B. The window part 42B is rectangular, is made of a resin, a glass, or the like, and is transparent or translucent.

The frame part 41B is made of a resin, and is constituted by a hollow portion 421 serving as a rectangular frame, an upper flange portion 422 extending from the upper long side of the hollow portion 421, and a lower flange portion 423 extending from the lower long side of the hollow portion 421. The window part 42B is surrounded by the hollow portion 421, and the upper flange portion 422 and the lower flange portion 423 protrude in the thickness direction of the hollow portion 421.

That is to say, the hollow portion 421 has a shape corresponding to the rectangular opening portion 314B, the upper flange portion 422 has a shape corresponding to the strip-shaped upper opening portion 312, and the lower flange portion 423 has a shape corresponding to the strip-shaped lower opening portion 323.

In the electrical junction box 100 according to Embodiment 4 having the above-described configuration, the user can immediately check, through the window part 42B of the lid member 40B, whether or not any fixed fuse 10 has been blown out.

Furthermore, the checking opening 33B is formed in the side plate 314A of the case member 30 that is closest to the plurality of fixed fuses 10. Therefore, the user can check whether or not any fuse 10 has been blown out, in a direction orthogonal to the thickness direction of the substrate 21, that is, from the side surface of the fixed fuses 10. Accordingly, as described above, even when the fixed fuses 10 have their own information indicated on the upper surface thereof, it is possible to reliably check whether or not any fixed fuse 10 has been blown out.

Also, since the checking opening 33B is covered with the lid member 40B, it is possible to prevent dust or the like from entering the case member 30 via the checking opening 33B.

Furthermore, since the lid member 40B can open and close, if any fixed fuse 10 is blown out, the user can open the lid member 40B, insert the distal end of a soldering iron into the case member 30 through the checking opening 33B to melt the solder, and remove and replace the blown-out fixed fuse 10.

Moreover, in the electrical junction box 100 according to Embodiment 4, the checking opening 33B is not only formed in the side plate 314A but also extends over the ceiling plate 313 and the bottom plate 321, the operation of replacing a fixed fuse 10 is easy and the operability can be increased.

The same reference numerals are given to the same components as those of Embodiment 1, and detailed descriptions thereof are omitted.

The embodiments disclosed herein are examples in all respects, and should be construed as non-limiting. The scope of the present invention is defined by the claims, and all modifications within the meaning and scope equivalent to the claims are intended to be included.

### List of Reference Numerals

10 Fixed fuse
11 Replaceable fuse
19 Holding terminal
20 Substrate assembly

### 21 Substrate

30 Case member
31 Upper case part
33, 33A, 33B Checking opening

### 34 Recess

40, 40A, 40B Lid member
41, 41A, 41B Frame part
42, 42A, 42B Window part
60 Connection port
61 Connection terminal
100 Electrical junction box
311 Replacement window
312 Strip-shaped upper opening portion
313 Ceiling plate
314 Side plate
314B Rectangular opening portion
315 Step part
317 Guide frame
321 Bottom plate
322 Side plate
323 Strip-shaped lower opening portion

1. An electrical junction box comprising a housing that houses a substrate to which a fuse is soldered,
wherein the housing includes a checking opening for checking whether or not the fuse has been blown out.

2. The electrical junction box according to claim 1 further comprising a lid member for covering the checking opening.

3. The electrical junction box according to claim 2,
wherein the lid member can open and close.

4. The electrical junction box according to claim 2 or 3,
wherein the lid member includes a transparent part.

5. The electrical junction box according to any one of claims 1 to 4,
wherein the housing has a flat cuboid shape,
the substrate is arranged facing two main surfaces of the housing, and
the checking opening is formed in one of the main surfaces at a position that corresponds to the fuse.

6. The electrical junction box according to any one of claims 1 to 4,
wherein the housing has a flat cuboid shape,
the substrate is arranged facing two main surfaces of the housing, and
the checking opening is formed in a side surface of the housing that is closest to the fuse.

7. The electrical junction box according to any one of claims 1 to 4,
wherein the housing has a flat cuboid shape,
the substrate is arranged facing two main surfaces of the housing, and
the checking opening is formed in a side surface of the housing that is closest to the fuse, while extending over the two main surfaces.
